(19) United States
(12) Patent Application Publication
(10) Pub. No.: US 2026/0247623 A1
(43) Pub. Date: Aug. 20, 2026

(54) SEMICONDUCTOR STRUCTURE AND METHOD FOR FORMING THE SAME

(71) Applicant: Winbond Electronics Corp., Taichung City (TW)

(72) Inventors: Hsing-Hao CHEN, Kaohsiung City (TW); Hao-Chuan CHANG, Kaohsiung City (TW)

(21) Appl. No.: 19/545,406

(22) Filed: Feb. 20, 2026

(30) Foreign Application Priority Data
Feb. 20, 2025 (TW) 114106189

(51) Int. Cl. H10B 43/35; H10D 30/67; H10W 20/00

(52) U.S. Cl. CPC H10B 43/35; H10D 30/6757; H10W 20/033; H10W 20/077; H10W 20/081; H10W 20/083

(57) ABSTRACT

A semiconductor structure and a method for forming the same are provided. The semiconductor structure includes a substrate, word line structures disposed on the substrate, and an insulating layer surrounding each word line structure. Each word line structure includes a conductive layer disposed on a lower portion of the word line structure, a filling layer disposed on an upper layer of the word line structure, and a block layer surrounding the filling layer. The block layer is a hydrogen-rich dielectric layer.

### CROSS REFERENCE TO RELATED APPLICATIONS

This Application claims priority of Taiwan Patent Application No. 114106189, filed on Feb. 20, 2025, the entirety of which is incorporated by reference herein.

### BACKGROUND OF THE INVENTION

### Field of the Invention

The present invention relates to a semiconductor structure, and, in particular, it relates to a semiconductor structure and a method for forming the same which reduces leakage current in word line structures.

### Description of the Related Art

Dynamic Random Access Memory (DRAM) devices are widely used in consumer electronic products. In order to increase the device density within a DRAM device and improve its overall performance, the manufacturing technology of DRAM devices continues to strive towards scaling down device sizes.

However, as device sizes continue to be scaled down, many challenges arise. For example, during the etching portion of the semiconductor manufacturing process, defects and surface dangling bonds may be generated in the silicon lattice, thereby causing a leakage current. Therefore, the industry still needs to improve the method of manufacturing dynamic random access memory devices to overcome the problems caused by the scaling down of component sizes.

### BRIEF SUMMARY OF THE INVENTION

The present invention provides a semiconductor structure, which includes a substrate, word line structures disposed on the substrate, and an insulating layer surrounding each word line structure. Each word line structure includes a conductive layer disposed on a lower portion of the word line structure, a filling layer disposed on an upper layer of the word line structure, and a block layer surrounding the filling layer. The block layer is a hydrogen-rich dielectric layer.

The present invention provides a method for forming a semiconductor structure, which includes providing a substrate; and forming a word line structure in the substrate. Forming the word structure comprises: forming a conductive layer on a lower portion of the word line structure; and forming a block layer and a filling layer on the conductive layer. The block layer is a hydrogen-rich dielectric layer.

### BRIEF DESCRIPTION OF THE DRAWINGS

The present invention can be more fully understood by reading the subsequent detailed description and examples with references made to the accompanying drawings, wherein:

FIGS. 1-6 are cross-sectional views showing semiconductor structures formed at different stages according to some embodiments of the present invention.

FIG. 7 is a partially enlarged cross-sectional view showing the semiconductor structure in FIG. 6 according to some embodiments of the present invention.

### DETAILED DESCRIPTION OF THE INVENTION

The present disclosure is described more fully below with reference to the drawings of the embodiments of the present invention. However, the present disclosure may be implemented in various different embodiments and should not be limited to the embodiments described herein. The thickness of layers and regions in the drawings may be exaggerated for clarity, and the same or similar reference numerals in the various drawings denote the same or similar elements.

The etching of word lines can cause defects in the silicon lattice, resulting in dangling bonds, which in turn cause leakage current. The embodiment of the present invention repairs lattice defects and reduces leakage current problems by forming a hydrogen-rich film layer.

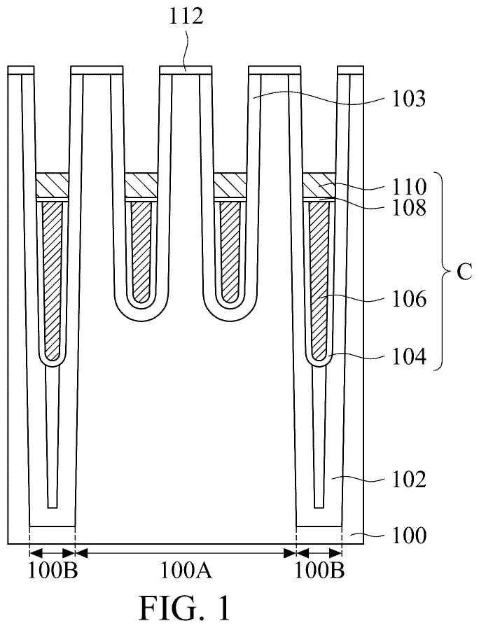

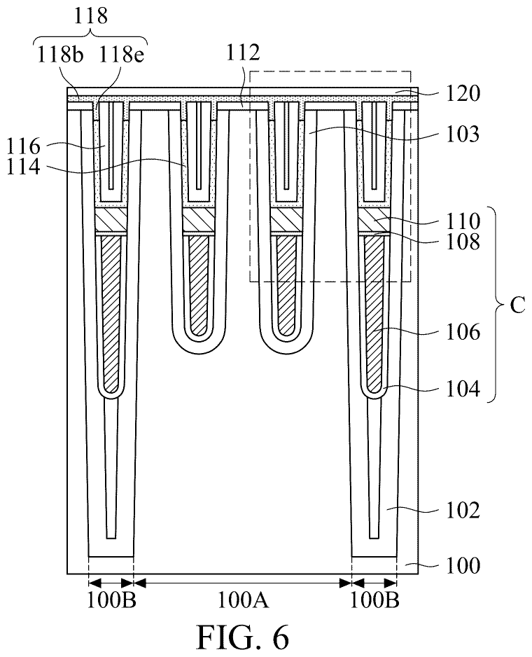

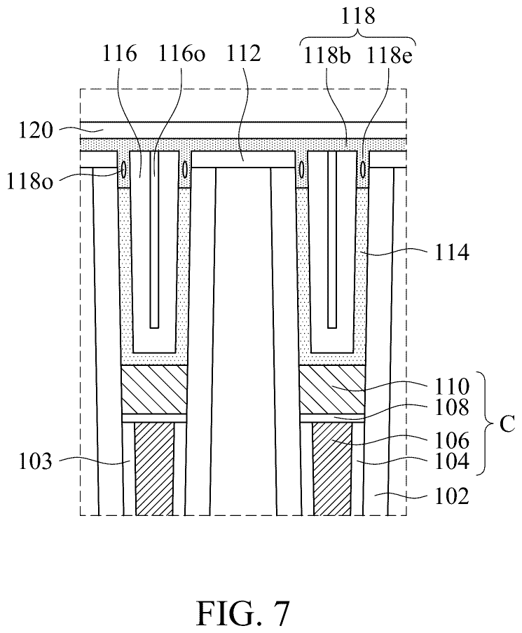

According to some embodiments of the present invention, FIGS. 1-6 are cross-sectional views showing semiconductor structures formed at different stages. FIG. 7 is a partially enlarged cross-sectional view showing the semiconductor structure in FIG. 6 according to some embodiments of the present invention. In some embodiments, the semiconductor structure is part of a dynamic random access memory array.

First, as shown in FIG. 1, a substrate 100 is provided. In some embodiments, the substrate 100 may be an elemental semiconductor substrate, such as a silicon substrate or a germanium substrate; or a compound semiconductor substrate, such as a silicon carbide substrate or a gallium arsenide substrate. In some embodiments, the substrate 100 may be a semiconductor-on-insulator substrate.

As shown in FIG. 1, a first cap layer 112 is formed on a substrate 100. In some embodiments, the first cap layer 112 may include a dielectric material, such as silicon oxide, silicon nitride, silicon oxynitride, or a high-k dielectric material. In this embodiment, the first cap layer 112 is made of silicon oxide to facilitate subsequent selective etching. In some embodiments, the formation of the first cap layer 112 may include a deposition process, such as chemical vapor deposition, molecular beam epitaxy, and the like.

As shown in FIG. 1, the substrate 100 includes a first region 100A and a second region 100B. The insulating layer 102 is formed in the second region 100B, and the insulating layer 103 is formed in the first region 100A. In some embodiments, the insulating layers 102 and 103 may be used to reduce interference between subsequently formed word line structures, and may be, for example, a single-layer film. In some embodiments, the insulating layer 103 may be an isolation structure formed by a plurality of films, such as a shallow trench isolation structure, but is not limited thereto.

In some embodiments, the insulating layer 102 and the insulating layer 103 may include nitride or oxide, such as silicon oxide, silicon nitride, silicon oxynitride, and/or combinations thereof. In some embodiments, the insulating layer 102 and the insulating layer 103 may also be in-situ steam-generated oxide layers, but the present invention is not limited thereto. In some embodiments, the formation of the insulating layer 102 and the insulating layer 103 may include a patterning process (for example, a lithography process and an etching process), a deposition process, and a planarization process (for example, chemical mechanical polishing). The etching process may include a dry etching process, a wet etching process, or other suitable etching processes. For example, plasma etching, ion milling reactive ion etching, neutral particle beam etching, and inductively coupled plasma etching. The etching process may also be pure chemical etching, pure physical etching, or a combination thereof.

Continuing as shown in FIG. 1, a conductive layer C is formed on the insulating layer 102 and/or the insulating layer 103. In some embodiments, the conductive layer C serves as a gate and includes a first barrier layer 104, a metal layer 106, a second barrier layer 108, and a semiconductor layer 110 in order from the substrate 100.

In some embodiments, a first barrier material and a metal material are first conformally deposited, and then the first barrier material and the metal material are etched back to a predetermined depth to obtain a first barrier layer 104 and a metal layer 106. Next, a second barrier material is deposited on the metal layer 106, and the second barrier material is etched back to obtain a second barrier layer 108. Next, a semiconductor material is deposited on the second barrier layer 108, and the semiconductor material is etched back to obtain a semiconductor layer 110. The deposition process and the etching process are similar to those described above and will not be described in detail here.

In some embodiments, the first barrier layer 104 and the second barrier layer 108 may include tungsten nitride, titanium nitride, or tantalum nitride. In some embodiments, the metal layer 106 may include a metal material, a metal alloy, such as tungsten, tungsten nitride, and the like. In some embodiments, the semiconductor layer 110 may include a semiconductor material, such as polysilicon.

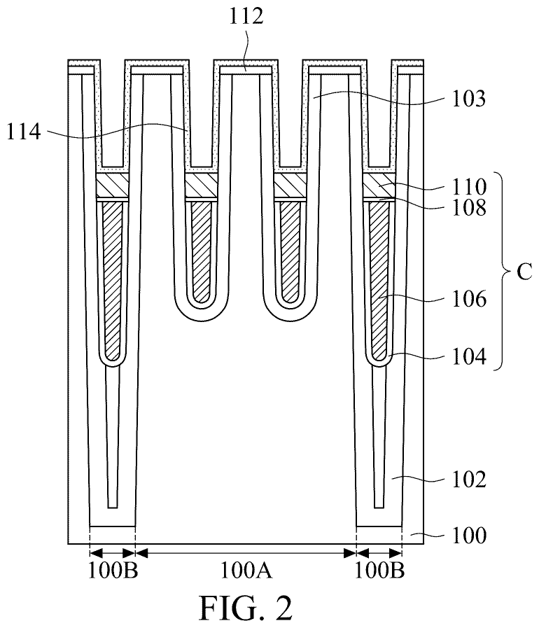

As shown in FIGS. 2-4, a barrier layer 114 and a filling layer 116 are formed on the conductive layer C. In this embodiment, the block layer 114 is made of a hydrogen-rich material so as to repair lattice defects with hydrogen atoms and prevent leakage current from being generated. In some embodiments, the block layer 114 may be a hydrogen-rich dielectric material, such as hydrogen-rich silicon oxide, hydrogen-rich silicon nitride, hydrogen-rich silicon oxynitride, or a hydrogen-rich high-k dielectric material. In this embodiment, the block layer 114 is hydrogen-rich silicon nitride.

In some embodiments, the filling layer 116 may be a dielectric material, such as silicon oxide, silicon nitride, silicon oxynitride, or a dielectric material with a high dielectric constant. In this embodiment, the filling layer 116 is silicon nitride. In some embodiments, the filling layer 116 may be a material containing hydrogen or not containing hydrogen. In this embodiment, the filling layer 116 and the barrier layer 114 are silicon nitride with different hydrogen ratios. For example, the barrier layer 114 has a higher hydrogen ratio than the filling layer 116. In other embodiments, the filling layer 116 is a material that does not contain hydrogen.

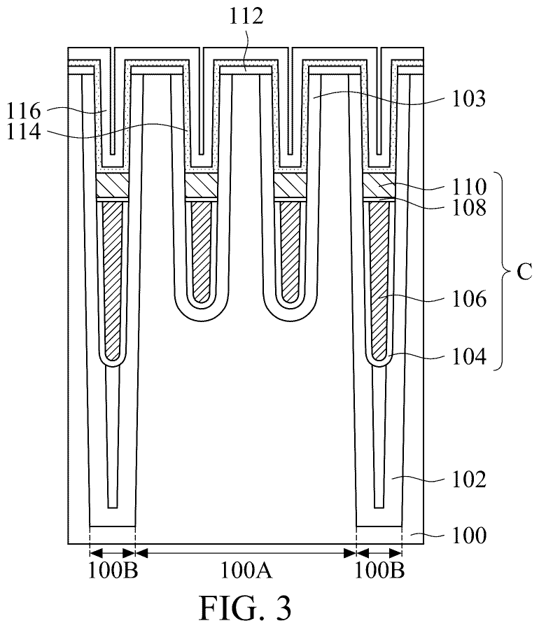

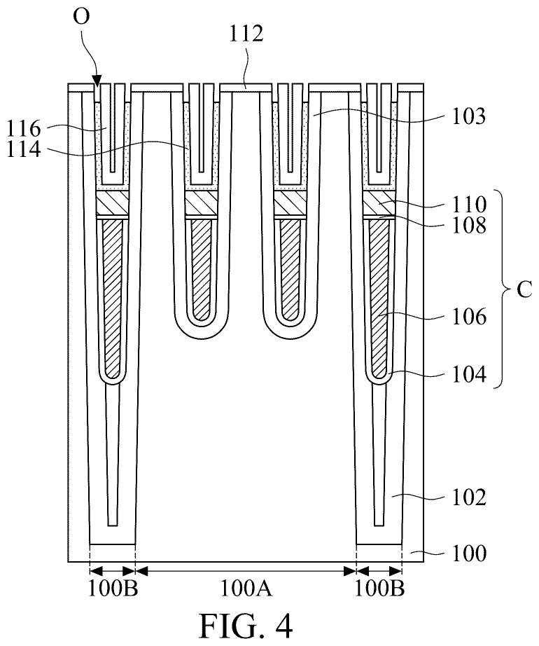

In some embodiments, after a barrier material is conformally deposited on the conductive layer C (FIG. 2), a filling material is conformally deposited on the barrier material (FIG. 3). Next, the filling material and the barrier material are etched back to form a barrier layer 114 and a filling layer 116 (FIG. 4). The deposition and etch-back processes are similar to those described above and will not be described in detail herein.

It should be noted that the first cap layer 112 illustrated in the present embodiment is silicon oxide, and thus may be used as an etching stop layer in the etch-back process. In addition, the block layer 114 and the filling layer 116 are silicon nitride with different hydrogen ratios, and therefore have different etching rates, resulting in a recess O on the formed block layer 114. That is, in FIG. 4, the top surface of the barrier layer 114 is lower than the top surface of the filling layer 116. The barrier layer 114 is disposed on the sidewall and the bottom of a portion of the filling layer 116.

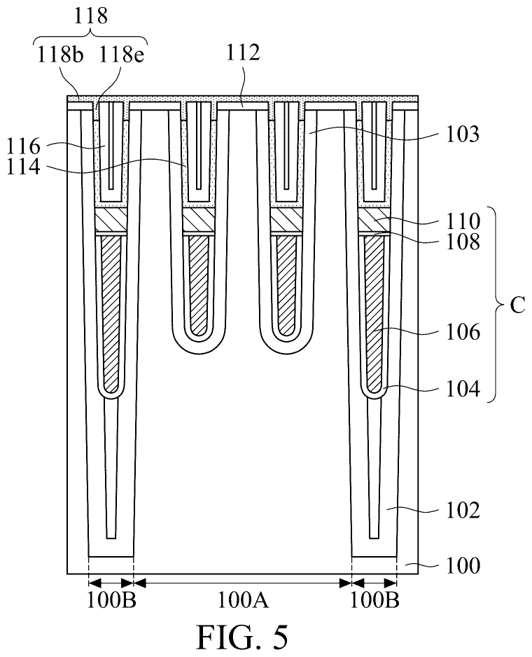

As shown in FIG. 5, a second cap layer 118 is formed on the barrier layer 114 and the first cap layer 112. In some embodiments, the second cap layer 118 includes a body portion 118b extending on the first cap layer 112 and an extending portion 118e extending from the bottom surface of the body portion 118b into the recess O. In some embodiments, the extending portion 118e is located on a portion of a sidewall of the filling layer 116 and contacts the barrier layer 114. In some embodiments, the bottom surface of the extending portion 118e is lower than the top surface of the filling layer 116. In some embodiments, the second cap layer 118 covers the top surface and a portion of the sidewall of the filling layer 116. That is, the second cap layer 118 and the barrier layer 114 cover the entire filling layer 116 together.

In some embodiments, depending on the aspect ratio of the recess O, the extending portion 118e may or may not form an air gap 118o therein. For example, in the enlarged cross-sectional view of FIG. 7, the extending portion 118e may form an air gap 118o therein.

In this embodiment, the second cap layer 118 is a hydrogen-rich material so as to repair the lattice defects on the surface of the substrate by hydrogen atoms, thereby preventing the generation of leakage current. In some embodiments, the second cap layer 118 may be a hydrogen-rich dielectric layer, which may be the same as or different from the barrier layer 114, such as hydrogen-rich silicon oxide, hydrogen-rich silicon nitride, hydrogen-rich silicon oxynitride, or a hydrogen-rich high-k dielectric material. In this embodiment, the second cap layer 118 is hydrogen-rich silicon nitride.

In some embodiments, the second cap layer 118 and the barrier layer 114 may be silicon nitride having the same or different hydrogen ratios. When the hydrogen ratio is the same, there is no boundary between the second cap layer 118 and the barrier layer 114, and the second cap layer 118 and the barrier layer 114 may be regarded as covering all side surfaces, top surfaces, and bottom surfaces of the filling layer 116. In the case where the hydrogen ratios are different, the second cap layer 118 may have a higher hydrogen ratio than the barrier layer 114, or the second cap layer 118 may have a lower hydrogen ratio than the barrier layer 114. In some embodiments, the formation of the second cap layer 118 includes a deposition process similar to the above, which will not be described in detail herein.

As shown in FIG. 6, a third cap layer 120 is formed on the second cap layer 118. In this embodiment, the third cap layer 120 may be used as a diffusion barrier layer to prevent hydrogen atoms from diffusing to the outside, which is beneficial to the capture of hydrogen atoms and further prevents the generation of leakage current. In some embodiments, the third cap layer 120 may be a dielectric layer, such as silicon oxide, silicon nitride, silicon oxynitride, or a high-k dielectric material. In some embodiments, the formation of the third cap layer 120 includes a deposition process similar to the above, which will not be described in detail herein.

FIG. 7 is a partially enlarged cross-sectional view of FIG. 6. As shown in FIG. 7, the filling layer 116 has air gaps 116o therein. In a common word line structure, the filling layer 116 has a large aspect ratio, so an air gap 116o is easily generated therein. In addition, in different implementations, the extending portion 118e in the second cap layer 118 may or may not generate an air gap 118o therein depending on its aspect ratio.

As described above, the embodiments of the present invention improve defects in the silicon lattice by forming a film layer having a hydrogen-rich dielectric layer in the word line structure, thereby further reducing the generation of leakage current.

Specifically, the semiconductor structure provided by the embodiment of the present invention includes a substrate, a word line structure disposed in the substrate, and an insulating layer covering the word line structure. The word line structure includes a conductive layer at the bottom and a filling layer at the top. The word line structure further includes a barrier layer extending on the sidewall and the bottom of the filling layer, and the barrier layer is a hydrogen-rich dielectric layer.

It should be understood that after the word line structure is formed, additional components such as contacts, capacitors, metal layers, and the like may still be formed to complete the fabrication of a memory element (such as a dynamic random access memory).

In summary, the embodiments of the present invention use a barrier layer having a hydrogen-rich dielectric layer to repair lattice defects and prevent the generation of leakage current. In addition, the embodiment of the present invention prevents the diffusion of hydrogen atoms by using a cap layer having a hydrogen-rich dielectric layer, and further captures hydrogen atoms to repair lattice defects, thereby preventing the generation of leakage current. Therefore, reliability and manufacturing yield are improved.

Although the present invention is disclosed as above with reference to the aforementioned embodiments, they are not intended to limit the present invention. Those skilled in the art may make some modifications and alterations without departing from the spirit and scope of the present invention. Therefore, the protection scope of the present invention shall be determined by the scope of the appended patent applications.

What is claimed is:

1. A semiconductor structure, comprising:
a substrate;
word line structures disposed in the substrate, wherein each word line structure comprises:
a conductive layer disposed on a lower portion of the word line structure;
a filling layer disposed on an upper layer of the word line structure; and
a block layer surrounding the filling layer, wherein the block layer is a hydrogen-rich dielectric layer; and
an insulating layer surrounding each of the word line structures.

2. The semiconductor structure as claimed in claim 1, wherein the block layer is disposed on a bottom and a sidewall of a portion of the filling layer.

3. The semiconductor structure as claimed in claim 1, wherein a top surface of the block layer is lower than a top surface of the filling layer.

4. The semiconductor structure as claimed in claim 1, further comprising:
a first cap layer disposed on the substrate; and
a second cap layer disposed on the first cap layer.

5. The semiconductor structure as claimed in claim 4, wherein the second cap layer is another hydrogen-rich dielectric layer.

6. The semiconductor structure as claimed in claim 4, wherein the second cap layer and the block layer have different hydrogen rates.

7. The semiconductor structure as claimed in claim 4, wherein the second cap layer is the hydrogen-rich dielectric layer.

8. The semiconductor structure as claimed in claim 4, wherein the second cap layer and the block layer have the same hydrogen rate.

9. The semiconductor structure as claimed in claim 4, wherein the second cap layer comprises:
a body portion disposed on the first cap layer; and
an extending portion extending from a bottom surface of the body portion to a portion of a sidewall of the filling layer and contacting the block layer.

10. The semiconductor structure as claimed in claim 9, wherein a bottom surface of the extending portion is lower than a top surface of the filling layer.

11. The semiconductor structure as claimed in claim 9, wherein the extending portion has an air gap therein.

12. The semiconductor structure as claimed in claim 4, further comprising:
a third cap layer disposed on the second cap layer.

13. The semiconductor structure as claimed in claim 12, wherein the third cap layer is another hydrogen-rich dielectric layer.

14. The semiconductor structure as claimed in claim 12, wherein the third cap layer and the second cap layer have different hydrogen rates.

15. The semiconductor structure as claimed in claim 12, wherein the third cap layer and the second cap layer have the same hydrogen rate.

16. The semiconductor structure as claimed in claim 1, wherein the conductive layer further comprises:
a metal layer disposed on a bottom of the conductive layer; and
a semiconductor disposed on the metal layer.

17. The semiconductor structure as claimed in claim 16, wherein the conductive layer further comprises:
a first barrier layer surrounding the metal layer; and
a second barrier layer disposed between the metal layer and the semiconductor.

18. A method for forming a semiconductor structure, comprising:
providing a substrate; and
forming a word line structure in the substrate, wherein forming the word structure comprises:
forming a conductive layer on a lower portion of the word line structure; and
forming a block layer and a filling layer on the conductive layer, wherein the block layer is a hydrogen-rich dielectric layer.

19. The method as claimed in claim 18, wherein forming the block layer and the filling layer comprises:
conformally depositing a block material layer on the conductive layer and on the substrate;
conformally depositing a filling material layer on the block material layer;
removing an excessive block material layer and an excessive filling material layer, so the block has a recess.

20. The method as claimed in claim 18, further comprising:
forming an insulating layer in the substrate before forming the word line structure;
forming a first cap layer on a top surface of the insulating layer and on a top surface of the substrate; and
sequentially forming a second cap layer and a third layer on the block layer and on the filling layer after forming the word line structure.
